(19) United States
(12) Patent Application Publication
(10) Pub. No.: US 2016/0042804 A1
(43) Pub. Date: Feb. 11, 2016

(54) ELECTRONIC APPARATUS AND ELECTRONIC FUSE THEREOF

(71) Applicant: ISSC Technologies Corp., Hsinchu (TW)

(72) Inventor: Che-Hong Chen, Hsinchu (TW)

(21) Appl. No.: 14/517,943

(22) Filed: Oct. 20, 2014

(30) Foreign Application Priority Data
Aug. 5, 2014 (TW) 103126769

(51) Int. Cl. G11C 17/18; G11C 17/16

(52) U.S. Cl. CPC G11C 17/18; G11C 17/16

(57) ABSTRACT

An electronic apparatus and an electronic fuse (e-fuse) thereof are provided. The e-fuse includes a transistor and a voltage selector. A first end of the transistor receives a power voltage, and a second end of the transistor is coupled to a reference ground voltage. The voltage selector receives a programming voltage and a read voltage, and outputs the programming voltage or the read voltage to a control end of the transistor according to a control signal. Wherein, the control signal is used to indicate the e-fuse being operated in a programming mode or a read mode. When the e-fuse is operated in the programming mode, the programming voltage is provided to the control end of the transistor for damaging a gate oxide layer of the transistor.

### CROSS-REFERENCE TO RELATED APPLICATION

This application claims the priority benefit of Taiwan application serial no. 103126769, filed on Aug. 5, 2014. The entirety of the above-mentioned patent application is hereby incorporated by reference herein and made a part of this specification.

### BACKGROUND OF THE INVENTION

1. Field of the Invention

The invention generally relates to an electronic fuse of an electronic apparatus.

2. Description of Related Art

Referring to FIG. 1, FIG. 1 illustrates a circuit diagram of a conventional electronic fuse 100. The conventional electronic fuse 100 includes a resistor FUSE and two transistors M1 and M2. The resistor FUSE is configured to be used as a fuse, and is connected in series with a programming voltage FSOURCE and the transistor M1. A gate of the transistor M1 receives a power voltage VDD, a source and a drain of the transistor M2 are respectively coupled between a drain of the transistor M1 and a reference ground voltage GND, and a gate of the transistor M2 receives a programming control signal BFUSE.

In terms of programming action, when the electronic fuse 100 performs the programming action, the programming control signal BFUSE is at a high voltage level and enable the transistor M2 to be turned on. As a result, the programming voltage FSOURCE may provide current to follow through the resistor FUSE and the transistors M1 and M2. By providing sufficiently large voltage of the programming voltage FSOURCE or enabling the programming voltage FSOURCE to provide sufficiently large driving current, the resistor FUSE may be blown to complete the programming action.

When performing a read action to the electronic fuse, an endpoint of the resistor FUSE for receiving the programming voltage FSOURCE may switched to connect with the reference ground voltage GND, and now, the programming control signal BFUSE is at a low voltage level and enables the transistor M2 to be disconnected. Under a condition whereby the resistor FUSE is blown, a reading endpoint ROUT would present a high impedance state, and under a condition whereby the resistor FUSE is not blown, a voltage value on the reading endpoint ROUT would equal to the reference ground voltage GND.

The blowing action of the resistor FUSE depicted in FIG. 1 requires a large enough current to be done, the superimposed transistors M1 and M2 in order to coordinate with the driving current during the programming also need a large layout area, and the blown resistor FUSE may often encounter recovery, thereby causing much inconveniences in actual practice.

### SUMMARY OF THE INVENTION

The invention provides an electronic fuse, which is capable of effectively saving area required for circuit layout.

The invention further provides an electronic apparatus, wherein an electronic fuse adopted thereby may effectively reduce area required for circuit layout.

The electronic fuse of the invention includes a transistor and a voltage selector. The transistor has a first end, a second end and a control end, wherein the first end of the transistor receives a power voltage, and the second end of the transistor is coupled to a reference ground voltage. The voltage selector receives a programming voltage and a read voltage, and outputs the programming voltage or the read voltage to the control end of the transistor according to a control signal. The control signal is used to indicate the electronic fuse being operated in a programming mode or a read mode. When the electronic fuse is operated in the programming mode, the programming voltage is provided to the control end of the transistor for damaging a gate oxide layer of the transistor. The read voltage is the reference ground voltage or the power voltage.

The electronic apparatus of the invention includes a core circuit and a setting device. The setting device is coupled to the core circuit for providing at least one setting code to the core circuit. The setting device includes at least one electronic fuse, and the at least one electronic fuse includes a transistor and a voltage selector. The transistor has a first end, a second end and a control end, wherein the first end of the transistor receives a power voltage, and the second end of the transistor is coupled to a reference ground voltage. The voltage selector receives a programming voltage and a read voltage, and outputs the programming voltage or the read voltage to the control end of the transistor according to a control signal. The control signal is used to indicated the at least one electronic fuse being operated in a programming mode or a read mode. When the at least one electronic fuse is operated in the programming mode, the programming voltage is proved to the control end of the transistor for damaging a gate oxide layer of the transistor. The read voltage is the reference ground voltage or the power voltage.

In of the above, the electronic fuse of the invention is constructed by a transistor in coordination with a simple voltage selector. Performing the programming action through damaging the gate oxide layer of the transistor may prevent the conventional resistor fuse from being recovered after blew. Moreover, as compared to the conventional resistor fuse, the programming voltage of the invention does not require an excessively high voltage value, and also does not have to provide an excessively large current driving ability, and thus may greatly lower the production cost and complexity.

To make the aforementioned and other features and advantages of the application more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a circuit diagram of a conventional electronic fuse.

FIG. 2 is a schematic diagram illustrating an electronic fuse according to an embodiment of the invention.

FIG. 3 is a schematic diagram illustrating an implementation of a voltage selector according to an embodiment of the invention.

FIG. 4 is a schematic diagram illustrating an implementation of the voltage selector according to another embodiment of the invention.

FIG. 5A is a schematic diagram illustrating an implementation of an electronic fuse under a read mode according to an embodiment of the invention.

FIG. 5B is a schematic diagram illustrating another implementation of the electronic fuse under the read mode according to an embodiment of the invention.

FIG. 6 is a schematic diagram illustrating an electronic apparatus according to an embodiment of the invention.

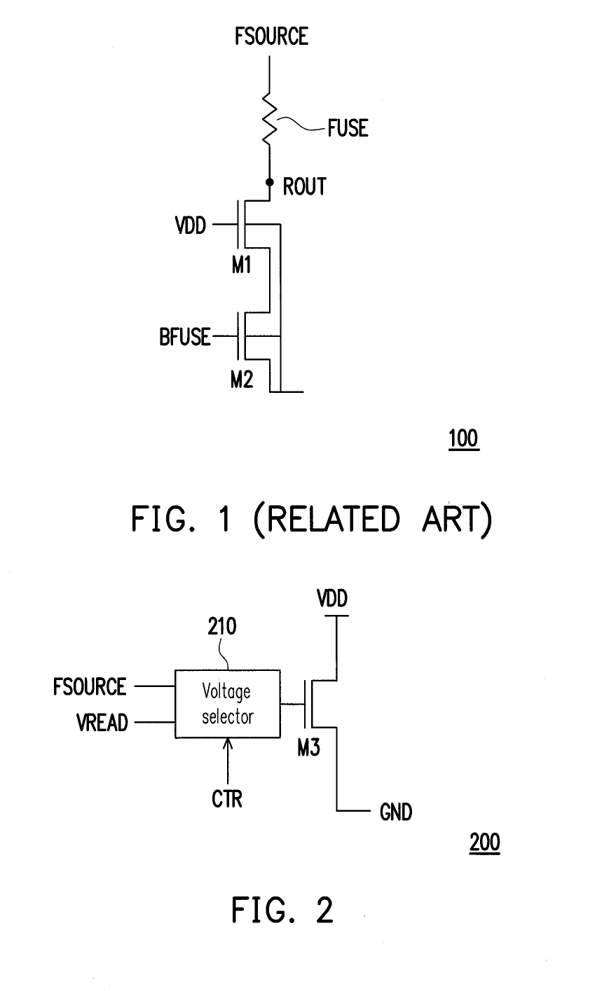

### DESCRIPTION OF THE EMBODIMENTS

Referring to FIG. 2, FIG. 2 is a schematic diagram illustrating an electronic fuse 200 according to an embodiment of the invention. The electronic fuse 200 includes a transistor M3 and a voltage selector 210. The transistor M3 has a first end, a second end and a control end. The first end of the transistor M3 receives a power voltage VDD, and the second end of the transistor M3 is coupled to a reference ground GND. The control end of the transistor M3 is coupled to an output terminal of the voltage selector 210. The voltage selector 210 receives a programming voltage FSOURCE and a read voltage VREAD. The voltage selector 210 outputs the programming voltage FSOURCE or the read voltage VREAD to the control end of the transistor M3 according to a control signal CTR.

In detail, the control signal CTR is used to indicate the electronic fuse 200 being operated in a programming mode or a read mode. When the control signal CTR indicates that the electronic fuse 200 is operated in the programming mode, the voltage selector 210 may output the programming voltage FSOURCE to the control end of the transistor M3 according to the control signal CTR. Relatively, when the control signal CTR indicates that the electronic fuse 200 is operated in the read mode, the voltage selector 210 may output the read voltage VREAD to the control end of the transistor M3 according to the control signal CTR.

When the electronic fuse 200 is operated in the programming mode, the programming voltage FSOURCE is selected to be outputted to the control end of the transistor M3 for damaging a gate oxide layer of the transistor M3. It is to be noted that, when the transistor M3 is a N-type enhancement metal oxide semiconductor field effect transistor (MOSFET), a base of the transistor M3 receives the reference ground voltage GND, and a voltage value of the programming voltage FSOURCE may be greater than a voltage value of the power voltage VDD. For example, in a 55 nm manufacturing process, the voltage value of the programming voltage FSOURCE being approximately 3 to 4 volts is sufficiently enough for damaging the gate oxide layer of the transistor M3. Relative, when the transistor M3 is a P-type enhancement metal oxide semiconductor field effect transistor (MOSFET), the base of the transistor M3 receives the power voltage VDD, and the voltage values of the programming voltage FSOURCE may be equal to a voltage value of the reference ground voltage GND or smaller than a negative voltage value of the reference ground voltage GND, and thus may damage the gate oxide layer of the transistor M3 through a voltage difference between the gate (the control end) and the base of the transistor M3.

Moreover, when the electronic fuse 200 is operated in the read mode, the voltage selector 210 is switched to output the read voltage VREAD to control end of the transistor M3. If the electronic fuse 200 has undergone a programming process, then a channel of the transistor M3 is unable to be effectively closed due to the gate oxide layer of the transistor M3 being damaged, and thus currents would pass between the first end and the second end of the transistor M3. Relatively, if the electronic fuse 200 has not undergone the programming process, then the channel of the transistor M3 may be effectively closed, and thus no current would pass between the first end and the second end of the transistor M3. It can be known from the above that, when the electronic fuse 200 is operated in the read mode, a status information of the electronic fuse 200 can be obtained by detecting a current status between the first end and the second end of the transistor M3.

Incidentally, when the transistor M3 is the N-type enhancement MOSFET, the read voltage VRED may be set equal to the reference ground voltage GND, and when the transistor M3 is the P-type enhancement MOSFET, the read voltage VRED may be set equal to the power voltage VDD.

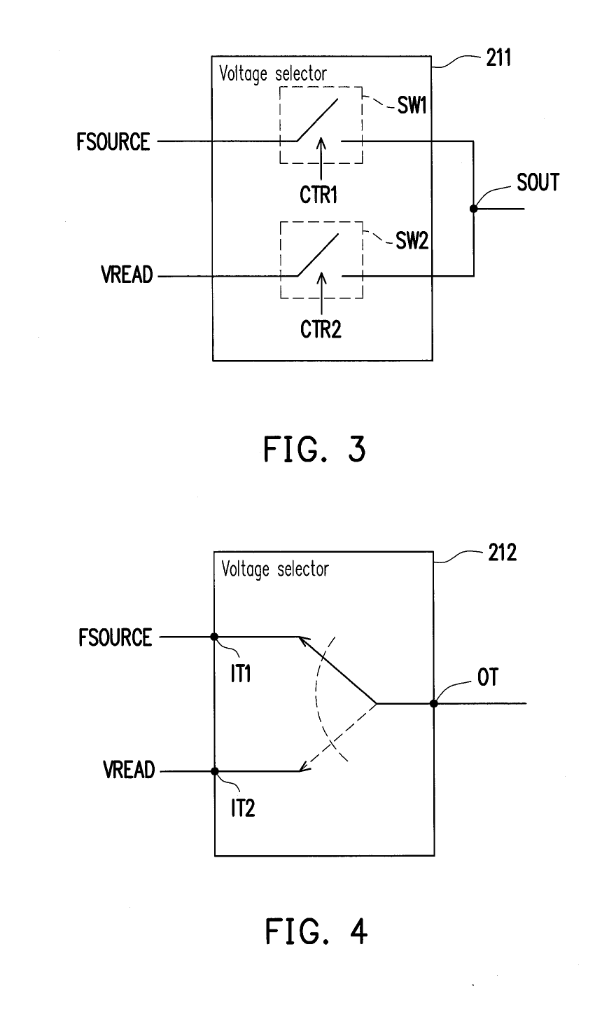

Referring to FIG. 3, FIG. 3 is a schematic diagram illustrating an implementation of the voltage selector 211 according to an embodiment of the invention. In FIG. 3, the voltage selector 211 includes a switch SW1 and a switch SW2. An end of the switch SW1 receives the programming voltage FSOURCE, while another end thereof is used as an output terminal SOUT of the voltage selector 211. An end of the switch SW2 receives the read voltage VREAD, while another end thereof is coupled to the output terminal SOUT of the voltage selector 211.

The switch SW1 and the switch SW2 are turned on or turned off according to a control signal CTR1 and a control signal CTR2, respectively. The control signal CTR1 is used to indicate the electronic fuse being in the programming mode, while the control signal CTR2 is used to indicate the electronic fuse being in the read mode. Namely, when the electronic fuse is in the programming mode, the control signal CTR1 enables the switch SW1 to be turned on; and when the electronic fuse is in the read mode, the control signal CTR2 enables the switch SW2 to be turned on. Incidentally, the switch SW1 and the switch SW2 do not be turned on at the same time.

Referring FIG. 4, FIG. 4 is a schematic diagram illustrating an implementation of a voltage selector 212 according to another embodiment of the invention. In FIG. 4, the voltage selector 212 has an input terminal IT1, an input terminal IT2 and an output terminal OT. The input terminal IT1 and the input terminal IT2 of the voltage selector 212 respectively receive the programming voltage FSOURCE and the read voltage VREAD, while the output terminal OT of the voltage selector 212 is coupled to the control end of the transistor M3. The voltage selector 212 connects the output terminal OT to the input terminal IT1 or the input terminal IT2 according to the control signal CTR. When the electronic fuse is in the programming mode, the voltage selector 212 connects the input terminal IT1 to the output terminal OT and outputs the programming voltage FSOURCE to the control end of the transistor M3 according to the control signal CTR. Relatively, when the electronic fuse is in the read mode, the voltage selector 212 connects the input terminal IT2 to the output terminal OT and outputs the read voltage VREAD to the control end of the transistor M3 according to the control signal CTR.

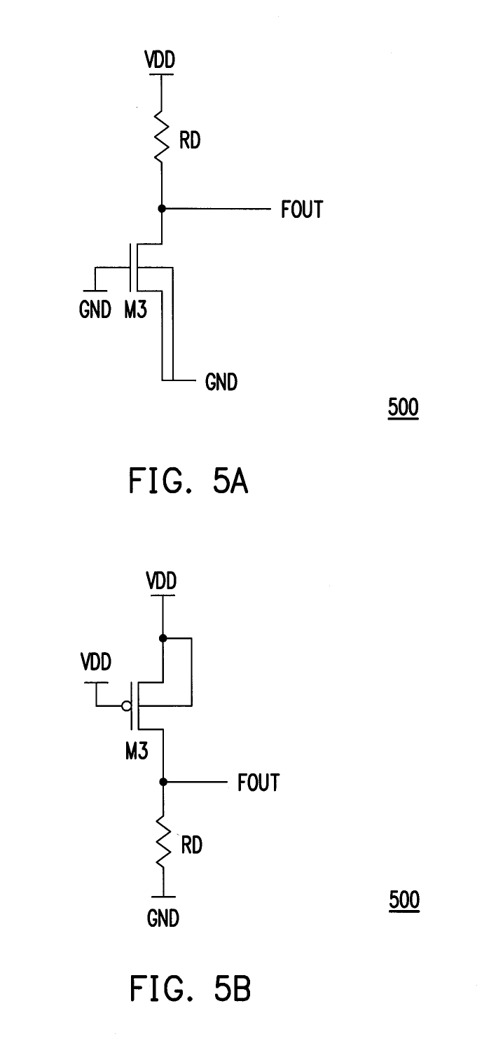

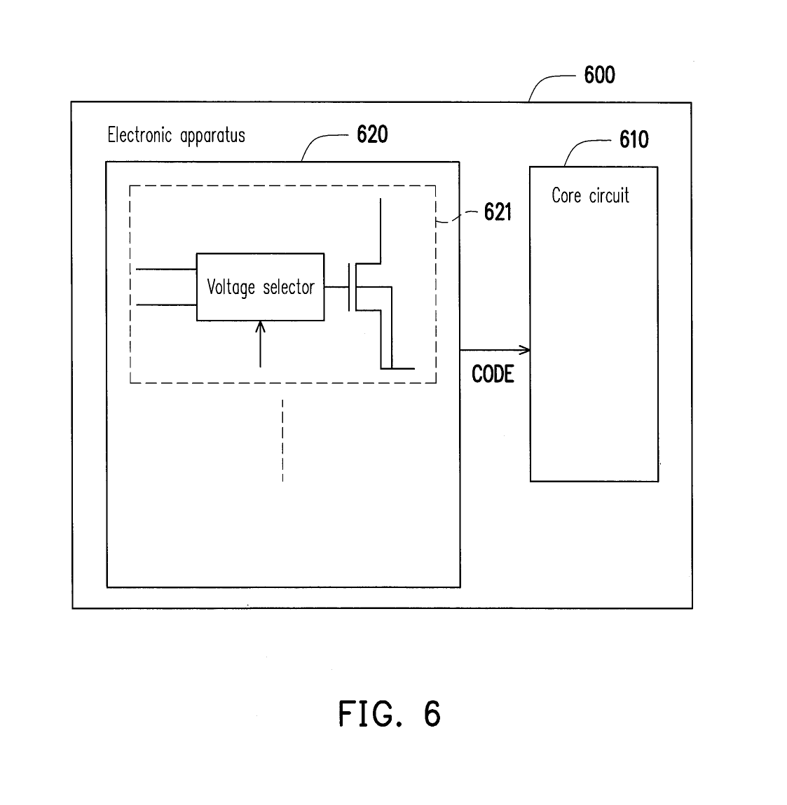

Referring to FIG. 5A, FIG. 5A is a schematic diagram illustrating an implementation of an electronic fuse 500 under a read mode according to an embodiment of the invention. In FIG. the transistor M3 is the N-type enhancement MOSFET. The transistor M3 is further connected with a resistor RD in series on a path for receiving the power voltage VDD. The second end and the control end of the transistor M3 are connected to the reference ground voltage GND. If the gate oxide layer of the transistor M3 has not yet been damaged (the electronic fuse 500 has not yet been programmed), then the channel of the transistor M3 would be closed according to the reference ground voltage GND received by the control end (such that no current is passing between the two ends of the transistor M3), and a reading information FOUT provided by the electronic fuse 500 would be equal to the power voltage VDD.

Moreover, if the gate oxide layer of the transistor M3 has been damaged (the electronic fuse 500 has been programmed), then the channel of the transistor M3 would not be closed according to the reference ground voltage GND received by the control end, and would continue to provide the path for currents to pass by (such that the currents are passing between the two ends of the transistor M3). Therefore, a voltage value of the reading information FOUT provided by the electronic fuse 500 would be smaller than the power voltage VDD.

Referring to FIG. 5B, FIG. 5B is a schematic diagram illustrating another implementation of the electronic fuse 500 under the read mode according to an embodiment of the invention. In FIG. 5B, the transistor M3 is the P-type enhancement MOSFET. The transistor M3 is further connected with a resistor RD in series on a path for receiving the reference ground voltage GND. The first end and the control end of the transistor M3 are connected to the power voltage VDD. If the gate oxide layer of the transistor M3 has not yet been damaged (the electronic fuse 500 has not yet been programmed), then the channel of the transistor M3 would be closed according to the power voltage VDD received by the control end (such that no current is passing between the two ends of the transistor M3), and the reading information FOUT provided by the electronic fuse 500 would be equal to the reference ground voltage GND.

Moreover, if the gate oxide layer of the transistor M3 has been damaged (the electronic fuse 500 has been programmed), then the channel of the transistor M3 would not be closed according to the power voltage VDD received by the control end, and would continue to provide the path for currents to pass by (such that the currents are passing between the two ends of the transistor M3). Therefore, a voltage value of the reading information FOUT provided by the electronic fuse 500 would be greater than the reference ground voltage GND.

Referring to FIG. 6, FIG. 6 is a schematic diagram illustrating an electronic apparatus 600 according to an embodiment of the invention. The electronic apparatus 600 includes a core circuit 610 and a setting device 620. The core circuit 610 is coupled to the setting device 620. The setting device 620 is configured to provide at least one setting code CODE to the core circuit 610. The core circuit 610 may receive the setting code CODE and set functions to be executed according to the setting code CODE. For example, if the core circuit 610 is a voltage generator, then the core circuit 610 may set the voltage value of an output voltage to be generated thereby according to the setting code CODE. If the core circuit 610 is a display driving circuit, then the core circuit 610 may set various screen display related parameters, such as resolution, scanning frequency and so forth, of a display panel to be driven thereby according to the setting code CODE.

Details regarding the exemplary embodiments of the core circuit 610 as described in the above are only provided as examples, and the invention is not limited thereto. Namely, the core circuit 610 may be any circuit known by those skilled in the art that is able to collectively perform operations with the electronic fuse.

The setting device 620 includes one or a plurality of electronic fuses 621. A single electronic fuse 621 under the read mode may be used to provide one bit of the setting code CODE to the core circuit 610. While, a plurality of electronic fuses 621 under the read mode may be used to provide multiple bits of the setting code CODE to the core circuit 610, wherein the amount of the electronic fuse 621 is the same as the number of the bit of the setting code CODE.

A user may change the setting code CODE provided by the electronic fuse 621 through programming the electronic fuse 621. From a digital logic perspective, a non-programmed electronic fuse 621 may provide a setting code with a logical value of 0 (or 1), whereas a programmed electronic fuse 621 may provide a setting code with a logical value of 1 (or 0).

In summary, the electronic fuse of the invention has a simple structure and does not require a large layout area. Moreover, the voltage value of the programming voltage for the programming process is not very big, and no large current value is required, thereby effectively saving energy consumption. In addition, the chance for the damaged gate oxide layer to be recovered is very low, thus providing no problem of incomplete programming.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electronic fuse comprising:
a transistor having a first end, a second end and a control end, wherein the first end of transistor receives a power voltage, and the second end of the transistor is coupled to a reference ground voltage; and
a voltage selector receiving a programming voltage and a read voltage, and outputting the programming voltage or the read voltage to the control end of transistor according to a control signal,
wherein the control signal is used to indicate the electronic fuse being operated in a programming mode or a read mode, when the electronic fuse is operated in the programming mode, the programming voltage is provide to the control end of the transistor for damaging a gate oxide layer of the transistor, and the read voltage is the reference ground voltage or the power voltage.

2. The electronic fuse as recited in claim 1, wherein a voltage value of the programming voltage is greater than a voltage value of the power voltage or not greater than the reference ground voltage.

3. The electronic fuse as recited in claim 1, wherein the voltage selector comprises:
a first switch having a first end coupled to the control end of the transistor and having a second end receiving the programming voltage, and the first switch is turned on under the programming mode; and
a second switch having a first end coupled to the control end of the transistor and having a second end receiving the read voltage, and the second switch is turned on under the read mode.

4. The electronic fuse as recited in claim 3, wherein the first switch and the second switch do not be turned on at the same time.

5. The electronic fuse as recited in claim 1, wherein the voltage selector has a first input terminal, a second input terminal and an output terminal, wherein the first input terminal and the second input terminal of the voltage selector respectively receive the programming voltage and the read voltage, and the output terminal of the voltage selector is coupled to the control end of the transistor,
wherein the voltage selector outputs the programming voltage or the read voltage to the output terminal of the voltage selector according to the control signal.

6. The electronic fuse as recited in claim 1, wherein the transistor is a N-type enhancement metal oxide semiconductor field effect transistor (MOSFET) or a P-type enhancement metal oxide semiconductor field effect transistor (MOSFET), when the transistor is the N-type enhancement MOSFET, the read voltage is the reference ground voltage, and when the transistor is the P-type enhancement MOSFET, the read voltage is the power voltage.

7. An electronic apparatus comprising:
a core circuit; and
a setting device coupled to the core circuit for providing at least one setting code to the core circuit, the setting device comprising:
at least one electronic fuse comprising:
a transistor having a first end, a second end and a control end, wherein the first end of the transistor received a power voltage, the second end of the transistor is coupled to a reference ground voltage; and
a voltage selector receiving a programming voltage and a read voltage, and outputting the programming voltage or the read voltage to the control end of the transistor according to a control signal,
wherein the control signal is used to indicate the electronic fuse being operated in a programming mode or a read mode, when the at least one electronic fuse is operated in the programming mode, the programming voltage is provide to the control end of the transistor for damaging a gate oxide layer of the, and the read voltage is the power voltage or the reference ground voltage,
wherein when the at least one electronic fuse is operated in the read mode, the at least one setting code is generated according to a current between the first end and the second end of the transistor, and the at least one setting code is provided to the core circuit for performing functional setup to the core circuit.

8. The electronic apparatus as recited in claim 7, wherein a voltage value of the programming voltage is greater than a voltage value of the power voltage or not greater than the reference ground voltage.

9. The electronic apparatus as recited in claim 7, wherein the transistor is a N-type enhancement metal oxide semiconductor field effect transistor (MOSFET) or a P-type enhancement metal oxide semiconductor field effect transistor (MOSFET), when the transistor is the N-type enhancement MOSFET, the read voltage is the reference ground voltage, and when the transistor is the P-type enhancement MOSFET, the read voltage is the power voltage.

10. The electronic apparatus as recited in claim 7, wherein the voltage selector comprises:
a first switch having a first end coupled to the control end of the transistor and having a second end receiving the programming voltage, and the first switch is turned on under the programming mode; and
a second switch having a first end coupled to the control end of the transistor and having a second end receiving the read voltage, and the second switch is turned on under the read mode,
wherein the first switch and the second switch do not turn on at the same time.
